(19) United States
(12) Patent Application Publication
(10) Pub. No.: US 2024/0322072 A1
(43) Pub. Date: Sep. 26, 2024

(54) METHOD FOR TRANSFERRING A LIGHT EMITTING DEVICE FOR DISPLAY

(71) Applicant: SEOUL VIOSYS CO., LTD., Ansan-si (KR)

(72) Inventor: Ik Kyu YOU, Ansan-si (KR)

(21) Appl. No.: 18/680,153

(22) Filed: May 31, 2024

Related U.S. Application Data
(63) Continuation of application No. 17/335,900, filed on Jun. 1, 2021.
(60) Provisional application No. 63/033,383, filed on Jun. 2, 2020.

(51) Int. Cl. H01L 33/00; H01L 25/075

(52) U.S. Cl. CPC H01L 33/0095; H01L 25/0753

(57) ABSTRACT

A transferring method for a light emitting device for a display includes manufacturing a wafer having unit pixels, cutting the wafer on a temporary substrate to singularize the unit pixels, measuring electrical or optical characteristics of the singularized unit pixels, and transferring unit pixels selected according to the electrical or optical characteristics to a carrier substrate. The selected unit pixels are transferred to the carrier substrate in a unit of a predetermined area encompassing a plurality of unit pixels.

### CROSS-REFERENCE TO RELATED APPLICATIONS

The patent document is a continuation of U.S. patent application Ser. No. 17/335,900, filed on Jun. 1, 2021, which claim priority to and the benefit of U.S. Provisional Application No. 63/033,383 filed Jun. 2, 2020. The aforementioned applications of which are incorporated herein by reference in their entireties.

### TECHNICAL FIELD

Exemplary embodiments relate to a method for transferring a light emitting device for a display.

### BACKGROUND

Recently, displays using ultra-small light emitting devices such as mini LEDs and micro LEDs have been developed. The mini LED is replacing a conventional backlight light source, and the micro LED can directly implement an image using LEDs without using a liquid crystal.

In general, a display apparatus realizes various colors through mixture of blue, green and red light. In order to realize various images, the display apparatus includes a plurality of pixels, each of which includes sub-pixels corresponding to blue, green and red light, respectively. A color of a certain pixel is determined based on the colors of the sub-pixels so that images may be realized through combination of such pixels.

In order to manufacture the display apparatus, a process of transferring light emitting devices from a wafer on which ultra-small light emitting devices are fabricated to a circuit board is carried out. In general, the ultra-small light emitting devices on the wafer are singularized or separated, and thereafter, transferred to a carrier substrate through the transferring process. The light emitting devices are arranged in a matrix shape on the carrier substrate, and the light emitting devices on the carrier substrate are finally transferred to the circuit board to manufacture the display apparatus.

However, some of the light emitting devices fabricated on the wafer do not meet required electrical and optical characteristics, and thus, these defective products need to be removed in advance before being transferred to the circuit board. Presence of the defective products makes it difficult to collectively transfer light emitting devices fabricated on the wafer to the carrier substrate. As a result, favorable light emitting devices, i.e., light emitting devices having good conditions, among the singularized light emitting devices on the wafer may be individually transferred to the carrier substrate using a pickup device such as a pick-and-place. However, in a case of mini LEDs or micro LEDs, the number of light emitting devices to be transferred is excessively large. Accordingly, the process of individually transferring the light emitting devices to the carrier substrate may have a disadvantage that takes too much time.

Meanwhile, the light emitting devices, fabricated together on the same wafer, exhibit various distributions in electrical and optical characteristics even in a case of collection of favorable products. In particular, there may be differences in electrical and optical characteristics of light emitting devices depending on regions on the wafer. For example, light emitting devices fabricated in a central region of the wafer may have higher or lower luminance than those fabricated in a peripheral region of the wafer, and may emit light of a shorter or a longer wavelength. The light emitting devices singularized on the wafer may be transferred to the circuit board while maintaining a relative locational relationship in the wafer. Accordingly, when the display apparatus manufactured using the light emitting devices is fabricated together on the same wafer, a higher luminance region and a lower luminance region may be formed, resulting in mura in a displayed image.

### SUMMARY

Exemplary embodiments provide a novel transferring method for a light emitting device for a display capable of shortening a process time.

Exemplary embodiments provide a transferring method for a light emitting device for a display capable of preventing an occurrence of mura in a displayed image.

A transferring method for a light emitting device for a display according to one or more exemplary embodiments includes manufacturing a wafer having unit pixels, cutting the wafer on a temporary substrate to singularize the unit pixels, measuring electrical or optical characteristics of the singularized unit pixels, and transferring unit pixels selected according to the electrical or optical characteristics to a carrier substrate. The selected unit pixels are transferred to the carrier substrate in a unit of a predetermined area encompassing a plurality of unit pixels.

A transferring method for a light emitting device for a display according to one or more exemplary embodiments, includes singularizing a plurality of unit pixels on a temporary substrate into individual unit pixels, measuring electrical characteristics, optical characteristics, or both of the individual unit pixels, selecting all or less unit pixels within a first predetermined area from the temporary substrate based on the electrical characteristics, the optical characteristics, or both, transferring the selected unit pixels to a second predetermined area of a carrier substrate and upon determination that the second predetermined area is not fully occupied with the selected unit pixels, filling in the second predetermined area with one or more unit pixels.

### DESCRIPTION OF DRAWINGS

FIG. 1 is a schematic plan view illustrating a display apparatus according to an exemplary embodiment.

FIG. 2 is a schematic plan view illustrating a pixel module according to an exemplary embodiment.

FIG. 3A is a schematic plan view illustrating a light emitting device according to an exemplary embodiment.

FIG. 3B is a schematic cross-sectional view taken along line A-A′ of FIG. 3A

FIG. 4A is a schematic plan view illustrating a unit pixel according to an exemplary embodiment.

FIG. 4B is a schematic cross-sectional view taken along line B-B′ of FIG. 4A

FIG. 4C is a schematic cross-sectional view taken along line C-C′ of FIG. 4A.

FIG. 5A is a schematic partial cross-sectional view taken along line D-D′ of FIG. 2 to describe a pixel module according to an exemplary embodiment.

FIG. 5B is a schematic partial cross-sectional view taken along line E-E′ of FIG. 2 to describe the pixel module according to an exemplary embodiment.

FIG. 6A is a schematic partial cross-sectional view taken along line D-D′ of FIG. 2 to describe a pixel module according to another exemplary embodiment.

FIG. 6B is a schematic partial cross-sectional view taken along line E-E′ of FIG. 2 to describe the pixel module according to another exemplary embodiment.

FIG. 7 is a schematic flowchart illustrating a manufacturing process of a display apparatus according to an exemplary embodiment.

FIGS. 8 through 11 are schematic cross-sectional views illustrating a method of transferring unit pixels to a carrier substrate using a transferring apparatus where:

FIG. 8 illustrates irradiating ultraviolet rays to unit pixels;

FIG. 9 illustrates a picker unit moving onto the unit pixels and contacting the unit pixels with a pickup head;

FIG. 10 illustrates moving the pickup head in the z direction and irradiating the unit pixels with ultraviolet rays; and

FIG. 11 illustrates transferring the unit pixels to a carrier substrate.

FIG. 12 is a schematic plan view illustrating unit pixels before being transferred to a carrier substrate.

FIGS. 13A through 13D are schematic plan views illustrating unit pixels while being transferred to a carrier substrate where:

FIG. 13A illustrates unit pixels R1 that are selectively separated from a first region PA1;

FIG. 13B illustrates the unit pixel R1 selectively separated from a second region PA2;

FIG. 13C illustrates the unit pixel R1 selectively separated from a third region PA3; and

FIG. 13D illustrates the unit pixels R1 selectively separated from a fourth region PA4.

FIG. 14 is a schematic plan view illustrating a carrier substrate during a process of transferring unit pixels according to an exemplary embodiment.

FIG. 15 is a schematic plan view illustrating a carrier substrate on which transferring of unit pixels is completed according to an exemplary embodiment.

FIG. 16 is a schematic plan view illustrating a carrier substrate on which transferring of unit pixels is completed according to another exemplary embodiment.

FIG. 17 is a schematic plan view illustrating a carrier substrate on which transferring of unit pixels is completed according to another embodiment.

### DETAILED DESCRIPTION OF EMBODIMENTS

Hereinafter, embodiments will be described in detail with reference to the accompanying drawings. The following embodiments are provided by way of example so as to fully convey the spirit of the present disclosure to those skilled in the art to which the present disclosure pertains. Accordingly, the present disclosure is not limited to the embodiments disclosed herein and can also be implemented in different forms. In the drawings, widths, lengths, thicknesses, and the like of elements may be exaggerated for clarity and descriptive purposes. When an element or layer is referred to as being “disposed above” or “disposed on” another element or layer, it may be directly “disposed above” or “disposed on” the other element or layer or intervening elements or layers may be present. Throughout the specification, like reference numerals denote like elements having the same or similar functions.

A transferring method for a light emitting device for a display according to one or more exemplary embodiments includes manufacturing a wafer having unit pixels, cutting the wafer on a temporary substrate to singularize the unit pixels, measuring electrical or optical characteristics of the singularized unit pixels, and transferring unit pixels selected according to the electrical or optical characteristics to a carrier substrate. The selected unit pixels are transferred to the carrier substrate in a unit of a predetermined area encompassing a plurality of unit pixels.

In at least one variant, the temporary substrate may include an ultraviolet tape being cured by ultraviolet irradiation.

In another variant, the selected unit pixels may be irradiated with ultraviolet rays so as to be separated from the temporary substrate. The ultraviolet rays may be irradiated in the unit of the predetermined area.

In further another variant, the unit pixel may include a blue light emitting device, a green light emitting device, and a red light emitting device. In an exemplary embodiment, the blue light emitting device, the green light emitting device, and the red light emitting device may be arranged on an identical plane. In another exemplary embodiment, the blue light emitting device, the green light emitting device, and the red light emitting device may be stacked on one another.

In another variant, the method may further include transferring the singularized unit pixels on the temporary substrate to an ultraviolet tape, in which the selected unit pixels may be transferred from the ultraviolet tape to the carrier substrate. The unit pixels selected within the predetermined area may be attached to a pickup head including an adhesive tape and transferred to the carrier substrate. Unit pixels fabricated on a single wafer may be divided and transferred to a plurality of carrier substrates.

The optical characteristics of the respective unit pixels may be measured by using a photoluminescence or an electroluminescence method.

The method may further include pressing the unit pixels on the carrier substrate to make elevations of the unit pixels uniform. Heat may be applied to the unit pixels while the unit pixels are pressed.

The selected unit pixels may be randomly arranged on the carrier substrate.

Two or more ranks may be determined for the unit pixels on the temporary substrate based on the electrical characteristics, the optical characteristics, or both of the unit pixels.

In one variant, the unit pixels of a same rank may be transferred to one carrier substrate.

In another variant, the unit pixels of different ranks may be mixed and transferred to the carrier substrate.

The unit pixels of different ranks may be disposed at a substantially identical ratio in predetermined areas of the carrier substrate.

A transferring method for a light emitting device for a display according to one or more exemplary embodiments, includes singularizing a plurality of unit pixels on a temporary substrate into individual unit pixels, measuring electrical characteristics, optical characteristics, or both of the individual unit pixels, selecting all or less unit pixels within a first predetermined area from the temporary substrate based on the electrical characteristics, the optical characteristics, or both, transferring the selected unit pixels to a second predetermined area of a carrier substrate and upon determination that the second predetermined area is not fully occupied with the selected unit pixels, filling in the second predetermined area with one or more unit pixels.

In another variant, filling in the second predetermined area further includes filling in the second predetermined area with the one or more unit pixels that are of the same rank as the selected unit pixels. The transferring method further includes transferring another selected set of unit pixels within a third predetermined area of the temporary substrate to a fourth predetermined area of the carrier substrate adjacent to the second predetermined area of the carrier substrate.

In another variant, selecting all or less unit pixels further includes determining two or more ranks for the individual unit pixels on the temporary substrate based on the electrical characteristics, the optical characteristics, or both of the unit pixels, and selecting two or more groups of the unit pixels of a same rank. Transferring the selected unit pixels further includes transferring the two or more groups of the unit pixels of same ranks to different carrier substrates, respectively.

In another variant, the transferring method further includes mixing the unit pixels of different ranks. Transferring the selected unit pixels further includes transferring mixed unit pixels of different ranks to the carrier substrate.

In another variant, the unit pixels of different ranks are disposed at a substantially identical ratio in the second predetermined areas of the carrier substrate.

Hereinafter, exemplary embodiments will be described in detail with reference to the accompanying drawings.

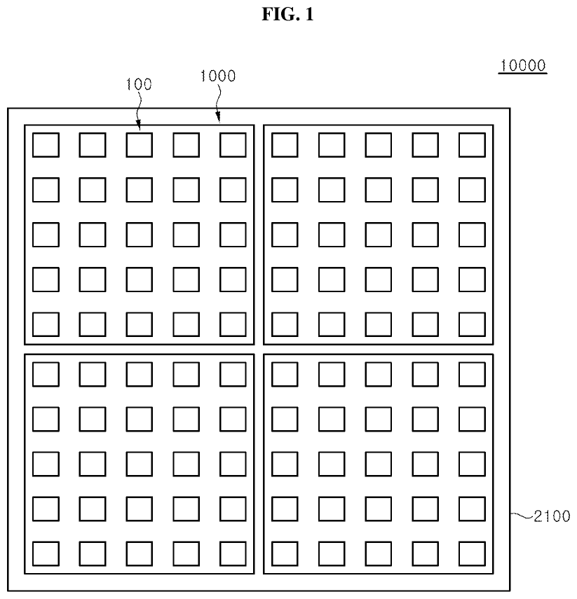

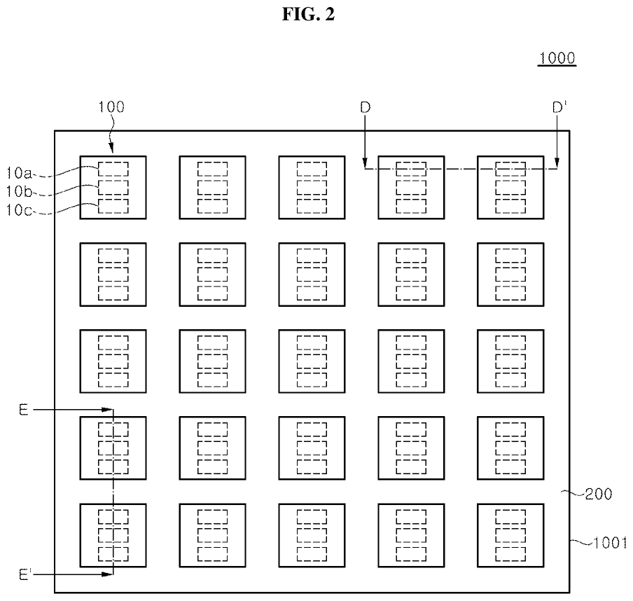

FIG. 1 is a schematic plan view illustrating a display apparatus 10000 according to an exemplary embodiment, and FIG. 2 is a schematic plan view illustrating a pixel module 1000 according to an exemplary embodiment.

Referring to FIGS. 1 and 2, the display apparatus 10000 may include a panel substrate 2100 and a plurality of pixel modules 1000.

The display apparatus 10000 is not particularly limited, but it may include a VR display apparatus such as a micro LED TV, a smart watch, a VR headset, or an AR display apparatus such as augmented reality glasses.

The panel substrate 2100 may include a passive matrix driving circuit or an active matrix driving circuit. In some forms, the panel substrate 2100 may include wirings and resistors therein, and, in another form, the panel substrate 2100 may include wirings, transistors, and capacitors. The panel substrate 2100 may also have pads that are capable of being electrically connected to the disposed circuit on an upper surface thereof.

In an exemplary embodiment, the plurality of pixel modules 1000 is arranged on the panel substrate 2100. Each of the pixel modules 1000 may include a circuit board 1001, a plurality of unit pixels 100 disposed on the circuit board 1001, and a molding member 200 covering the unit pixels 100. In another exemplary embodiment, the plurality of unit pixels 100 may be directly arranged on the panel substrate 2100, and the molding member 200 may cover the unit pixels 100.

Each of the unit pixels 100 also includes a plurality of light emitting devices 10a, 10b, and 10c. The light emitting devices 10a, 10b, and 10c may emit light of different colors from one another. The light emitting devices 10a, 10b, and 10c in each of the unit pixels 100 may be arranged in a line as shown in FIG. 2. In some forms, the light emitting devices 10a, 10b, and 10c may be arranged in a vertical direction with respect to a display screen on which the image is displayed. However, the inventive concepts are not limited thereto, and the light emitting devices 10a, 10b, and 10c may be arranged in a lateral direction with respect to the display screen on which the image is displayed.

If the light emitting devices 10a, 10b, and 10c may be directly mounted on the panel substrate 2100, mounting failure of light emitting devices, which may be difficult to handle, is likely to occur. If the mounting failure may occur, the panel substrate 2100 and all of the light emitting devices are discarded, resulting in significant waste. Meanwhile, after the unit pixels 100 on which the light emitting devices 10a, 10b, and 10c are mounted are manufactured first, favorable unit pixels 100 having good conditions are selected to be mounted on the panel substrate 2100. Accordingly, cost loss caused by a failed device may be reduced.

Hereinafter, each element of the display apparatus 10000 will be described in detail in the order of the light emitting device 10a, 10b, and 10c, the unit pixel 100, and the pixel module 1000 that are disposed in the display apparatus 10000.

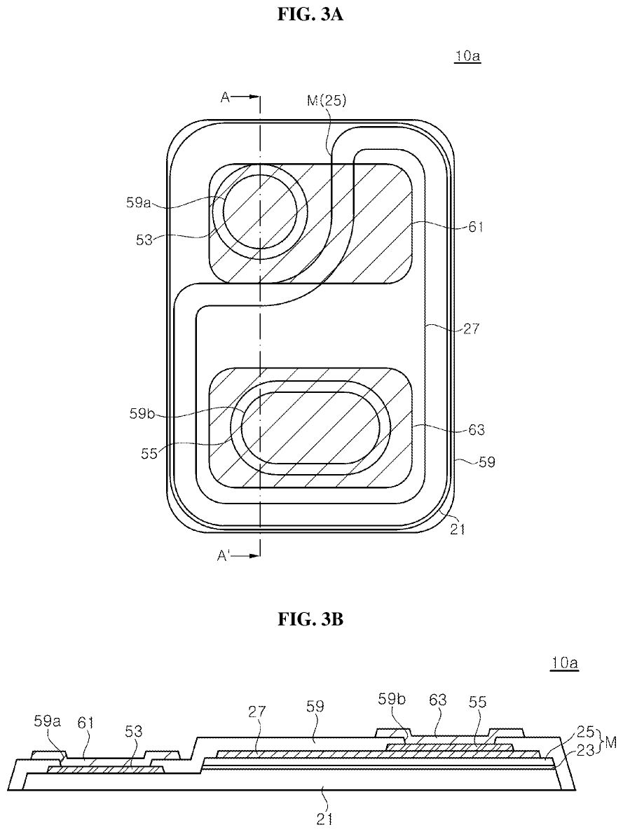

First, FIG. 3A is a schematic plan view illustrating the light emitting device 10a according to an exemplary embodiment, and FIG. 3B is a schematic cross-sectional view taken along line A-A′ of FIG. 3A. Herein, the light emitting device 10a is exemplarily described, but since the light emitting devices 10b and 10c have a substantially similar structure to that of the light emitting device 10a, repeated descriptions thereof will be omitted.

Referring to FIGS. 3A and 3B, the light emitting device 10a may include a light emitting structure including a first conductivity type semiconductor layer 21, an active layer 23, and a second conductivity type semiconductor layer 25, an ohmic contact layer 27, a first contact pad 53, a second contact pad 55, an insulation layer 59, a first electrode pad 61, and a second electrode pad 63.

The light emitting device 10a may have a rectangular shape having a long axis and a short axis as viewed in plan view. For example, a length of the long axis may have a size of 100 μm or less, and a length of the short axis may have a size of 70 μm or less. The light emitting devices 10a, 10b, and 10c may have substantially similar shapes and sizes to one another.

The light emitting structure, that is, the first conductivity type semiconductor layer 21, the active layer 23, and the second conductivity type semiconductor layer 25 may be grown on a substrate. The substrate may be one of various substrates that are used to grow semiconductors, such as a gallium nitride substrate, a GaAs substrate, a Si substrate, a sapphire substrate, especially a patterned sapphire substrate. The growth substrate may be separated from the semiconductor layers using a process such as a mechanical grinding, a laser lift off, a chemical lift off process, or the like. However, the inventive concepts are not limited thereto, and, in some exemplary embodiments, a portion of the substrate may remain to constitute at least a portion of the first conductivity type semiconductor layer 21.

When the light emitting device 10a emits red light according to an exemplary embodiment, the semiconductor layers may include aluminum gallium arsenide (AlGaAs), gallium arsenide phosphide (GaAsP), aluminum gallium indium phosphide (AlGaInP), or gallium phosphide (GaP).

When the light emitting device 10b emits green light, the semiconductor layers may include indium gallium nitride (InGaN), gallium nitride (GaN), gallium phosphide (GaP), aluminum gallium indium phosphide (AlGaInP), or aluminum gallium phosphide (AlGaP).

When the light emitting device 10c emits blue light according to an exemplary embodiment, the semiconductor layers may include gallium nitride (GaN), indium gallium nitride (InGaN), or zinc selenide (ZnSe).

The first conductivity type and the second conductivity type have opposite polarities, such as when the first conductivity type is an n-type, the second conductivity type becomes a p-type, or when the first conductivity type is a p-type, the second conductivity type becomes an n-type.

The first conductivity type semiconductor layer 21, the active layer 23, and the second conductivity type semiconductor layer 25 may be grown on the substrate in a chamber using a known process such as metal organic chemical vapor deposition (MOCVD) process. In addition, the first conductivity type semiconductor layer 21 includes n-type impurities (e.g., Si, Ge, and Sn), and the second conductivity type semiconductor layer 25 includes p-type impurities (e.g., Mg, Sr, and Ba). In a case of the light emitting device 10b or 10c emitting green or blue light, the first conductivity type semiconductor layer 21 may include GaN or AlGaN containing Si as a dopant, and the second conductivity type semiconductor layer 25 may include GaN or AlGaN containing Mg as a dopant.

Although the first conductivity type semiconductor layer 21 and the second conductivity type semiconductor layer 25 are shown as single layers in FIG. 3B, these layers may be multiple layers, and may also include a superlattice layer. The active layer 23 may include a single quantum well structure or a multiple quantum well structure, and a composition ratio of a compound semiconductor may be adjusted to emit a desired wavelength. For example, the active layer 23 may emit blue light, green light, red light, or ultraviolet light.

The second conductivity type semiconductor layer 25 and the active layer 23 may have a mesa M structure and may be disposed on the first conductivity type semiconductor layer 21. The mesa M may include the second conductivity type semiconductor layer 25 and the active layer 23, and may include a portion of the first conductivity type semiconductor layer 21 as shown in FIG. 3B. The mesa M may be disposed on the portion of the first conductivity type semiconductor layer 21, and an upper surface of the first conductivity type semiconductor layer 21 may be exposed around the mesa M.

In some forms, the mesa M is formed so as to expose the first conductivity type semiconductor layer 21 around it. In another form, a through hole may be formed through the mesa M to expose the first conductivity type semiconductor layer 21.

In some forms, the first conductivity type semiconductor layer 21 may have a flat light exiting surface. In another form, the first conductivity type semiconductor layer 21 may have a concave-convex pattern by surface texturing on a side of the light exiting surface. Surface texturing may be carried out by patterning, for example, using a dry or wet etching process. For example, cone-shaped protrusions may be formed on the light exiting surface of the first conductivity type semiconductor layer 21, a height of the cone may be about 2 μm to about 3 μm, a distance between the cones may be about 1.5 μm to about 2 μm, and a diameter of a bottom of the cone may be about 3 μm to about 5 μm. The cone may also be truncated, in which case an upper diameter of the cone may be about 2 μm to about 3 μm.

In another form, the concave-convex pattern may include a first concave-convex pattern and a second concave-convex pattern additionally formed on the first concave-convex pattern.

As the concave-convex pattern is formed on the surface of the first conductivity type semiconductor layer 21, total internal reflection may be reduced, thereby increasing light extraction efficiency. Surface texturing may be carried out on the first conductivity type semiconductor layers of all of the first, second, and third light emitting devices 10a, 10b, and 10c, and thus, viewing angles of light emitted from the first, second, and third light emitting devices 10a, 10b, and 10c may become uniform. However, the inventive concepts are not limited thereto, and at least one of the light emitting devices 10a, 10b, and 10c may have the flat surface without including the concave-convex pattern.

The ohmic contact layer 27 is disposed on the second conductivity type semiconductor layer 25 to be in ohmic contact with the second conductivity type semiconductor layer 25. The ohmic contact layer 27 may be formed of a single layer or multiple layers, and may be formed of a transparent conductive oxide film or a metal film. For example, the transparent conductive oxide film may include ITO, ZnO, or the like, and the metal film may include a metal such as Al, Ti, Cr, Ni, Au, or the like and alloys thereof.

The first contact pad 53 is disposed on the exposed first conductivity type semiconductor layer 21. The first contact pad 53 may be in ohmic contact with the first conductivity type semiconductor layer 21. For example, the first contact pad 53 may be formed of an ohmic metal layer in ohmic contact with the first conductivity type semiconductor layer 21. The ohmic metal layer of the first contact pad 53 may be appropriately selected depending on a semiconductor material of the first conductivity type semiconductor layer 21. The first contact pad 53 may be omitted.

The second contact pad 55 may be disposed on the ohmic contact layer 27. The second contact pad 55 is electrically connected to the ohmic contact layer 27. The second contact pad 55 may be omitted.

The insulation layer 59 covers the mesa M, the ohmic contact layer 27, the first contact pad 53, and the second contact pad 55. The insulation layer 59 has openings 59a and 59b exposing the first contact pad 53 and the second contact pad 55. The insulation layer 59 may be formed as a single layer or multiple layers. Furthermore, the insulation layer 59 may include a distributed Bragg reflector in which insulation layers having different refractive indices from one another are stacked. For example, the distributed Bragg reflector may include at least two types of insulation layers selected from SiO₂, Si₃N₄, SiON, TiO₂, Ta₂O₅, and Nb₂O₅.

The distributed Bragg reflector reflects light emitted from the active layer 23. The distributed Bragg reflector may exhibit high reflectance over a relatively wide wavelength range including a peak wavelength of light emitted from the active layer 23, and may be designed in consideration of an incident angle of light. In an exemplary embodiment, the distributed Bragg reflector may have a higher reflectance for light incident at an incident angle of 0 degrees than that for light incident at a different incident angle. In another exemplary embodiment, the distributed Bragg reflector may have a higher reflectance for light incident at a particular incident angle than that for light incident at the incident angle of 0 degrees. For example, the distributed Bragg reflector may have a higher reflectance for light incident at an incident angle of 10 degrees than thar for light incident at the incident angle of 0 degrees.

Meanwhile, the light emitting structure of the blue light emitting device 10c has higher internal quantum efficiency compared to those of the light emitting structures of the red light emitting device 10a and the green light emitting device 10b. Accordingly, the blue light emitting device 10c may exhibit higher light extraction efficiency than those of the red and green light emitting devices 10a and 10b. As such, it may be difficult to properly maintain a color mixing ratio of red light, green light, and blue light.

To adjust the color mixing ratio of red light, green light, and blue light, the distributed Bragg reflectors applied to the light emitting devices 10a, 10b, and 10c may be formed to have different reflectance from one another. For example, the blue light emitting device 10c may have the distributed Bragg reflector having a relatively low reflectance compared to those of the red and green light emitting devices 10a and 10b. For example, the distributed Bragg reflector formed in the blue light emitting device 10c may have a reflectance of 95% or less at the incident angle of 0 degrees for blue light generated in the active layer 23, and further 90% or less, the distributed Bragg reflector formed in the green light emitting device 10b may have a reflectance of about 95% or more and 99% or less at the incident angle of 0 degrees for green light, and the distributed Bragg reflector formed in the red light emitting device 10a may have a reflectance of 99% or more at the incident angle of 0 degrees for red light.

In some forms, the distributed Bragg reflectors applied to the red, green, and blue light emitting devices 10a, 10b, and 10c may have a substantially similar thickness. For example, a difference in thickness between the distributed Bragg reflectors applied to these light emitting devices 10a, 10b, and 10c may be 10% or less of a thickness of a thickest distributed Bragg reflector. By reducing the thickness difference between the distributed Bragg reflectors, process conditions applied to the red, green, and blue light emitting devices 10a, 10b, and 10c, for example, a process of patterning the insulation layer 59, may be similarly set, and furthermore, it is possible to prevent the unit pixel manufacturing process from becoming complex. Moreover, the distributed Bragg reflectors applied to the red, green, and blue light emitting devices 10a, 10b, and 10c may have a substantially similar stacking number. However, the inventive concepts are not limited thereto.

The first electrode pad 61 and the second electrode pad 63 are disposed on the insulation layer 59. The first electrode pad 61 may extend from an upper region of the first contact pad 53 to an upper region of the mesa M, and the second electrode pad 63 may be disposed in the upper region of the mesa M. The first electrode pad 61 may be connected to the first contact pad 53 through the opening 59a, and the second electrode pad 63 may be electrically connected to the second contact pad 55. The first electrode pad 61 may be directly in ohmic contact with the first conductivity type semiconductor layer 21, and in this case, the first contact pad 53 may be omitted. In addition, when the second contact pad 55 is omitted, the second electrode pad 63 may be directly connected to the ohmic contact layer 27.

The first and/or second electrode pads 61 and 63 may be formed of a single layer or a multiple layer of metal. As a material of the first and/or second electrode pads 61 and 63, a metal such as Al, Ti, Cr, Ni, Au, or the like and an alloy thereof or the like may be used. For example, the first and second electrode pads 61 and 63 may include a Ti layer or a Cr layer at an upper most layer, and may include an Au layer thereunder.

Although the light emitting device 10a according to the exemplary embodiment has been briefly described with reference to FIGS. 3A and 3B, the light emitting device 10a may further include a layer having additional functions in addition to the above-described layers. For example, various layers such as a reflective layer for reflecting light, an additional insulation layer for insulating a specific element, and a solder preventing layer for preventing diffusion of solder may be further included.

When a flip chip type light emitting device is formed, the mesa may be formed to have various shapes, and locations and shapes of the first and second electrode pads 61 and 63 may also be variously modified, and the second contact pad 55 or the second electrode pad 63 may directly contact the second conductivity type semiconductor layer 25.

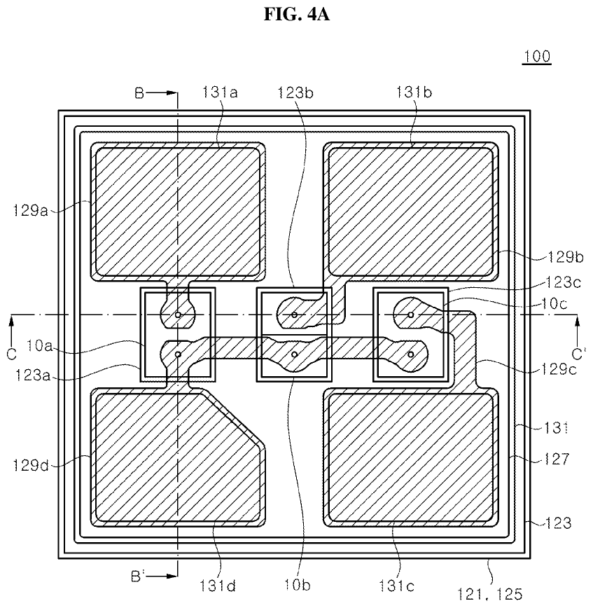

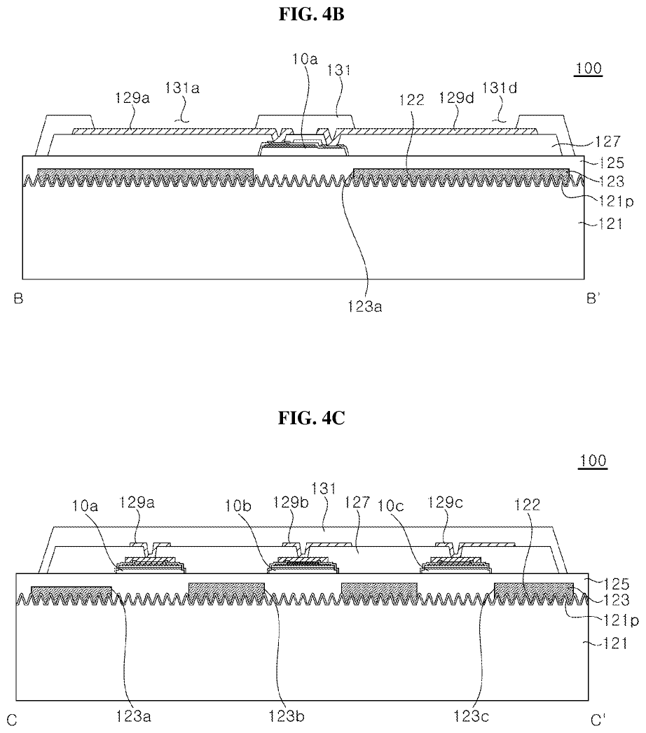

FIG. 4A is a schematic plan view illustrating a unit pixel 100 according to an exemplary embodiment, FIG. 4B is a schematic cross-sectional view taken along line B-B′ of FIG. 4A, and FIG. 4C is a schematic cross-sectional view taken along line C-C′ of FIG. 4A.

Referring to FIGS. 4A, 4B, and 4C, the unit pixel 100 may include a transparent substrate 121, a first, a second, and a third light emitting devices 10a, 10b, and 10c, a surface layer 122, a light blocking layer 123, an adhesive layer 125, a step adjustment layer 127, connection layers 129a, 129b, 129c, and 129d, and an insulation material layer 131

The unit pixel 100 provides a single pixel including the first, second, and third light emitting devices 10a, 10b, and 10c. The first, second, and third light emitting devices 10a, 10b, and 10c emit light of different colors, and the first, second, and third light emitting devices 10a, 10b, and 10c correspond to subpixels, respectively.

The transparent substrate 121 is a light transmissive substrate such as PET, glass substrate, quartz, sapphire substrate, or the like. The transparent substrate 121 is disposed on a light exiting surface of the display apparatus 10000 of FIG. 1, and light emitted from the light emitting devices 10a, 10b, and 10c is emitted to the outside through the transparent substrate 121. The transparent substrate 121 may have an upper surface and a lower surface. The transparent substrate 121 may include a concave-convex pattern 121p on a surface facing the light emitting devices 10a, 10b, and 10c, that is, the upper surface. The concave-convex pattern 121p scatters light emitted from the light emitting devices 10a, 10b, and 10c to increase a viewing angle. In addition, light emitted from the light emitting devices 10a, 10b, and 10c having different viewing angle characteristics from one another may be emitted at a uniform viewing angle by the concave-convex pattern 121p. As such, it is possible to prevent an occurrence of color difference depending on the viewing angle.

The concavo-convex pattern 121p may be regular or irregular. The concavo-convex pattern 121P may have a pitch of about 3 μm, a diameter of about 2.8 μm, and a height of about 1.8 μm, for example. The concavo-convex pattern 121p may be a pattern generally applied to a patterned sapphire substrate, but it is not limited thereto.

The transparent substrate 121 may also include an anti-reflection coating, may include an anti-glare layer, or may be treated with an anti-glare treatment. The transparent substrate 121 may have a thickness of about 50 μm to about 300 μm for example.

As the transparent substrate 121 is disposed on the light exiting surface, the transparent substrate 121 does not include a circuit. However, the inventive concepts are not limited thereto, and, in some exemplary embodiments, the transparent substrate 121 may include the circuit.

Although a single unit pixel 100 is illustrated to be formed on a single transparent substrate 121, a plurality of unit pixels 100 may be formed on the single transparent substrate 121.

The surface layer 122 covers the concave-convex pattern 121p of the transparent substrate 121. The surface layer 122 may be formed along a shape of the concave-convex pattern 121p. The surface layer 122 may improve adhesion of the light blocking layer 123 formed thereon. For example, the surface layer 122 may be formed of a silicon oxide film. The surface layer 122 may be omitted depending on a type of the transparent substrate 121.

The light blocking layer 123 is formed on the upper surface of the transparent substrate 121. The light blocking layer 123 may contact the surface layer 122. The light blocking layer 123 may include an absorbing material which absorbs light such as carbon black. The light absorbing material may prevent light generated in the light emitting devices 10a, 10b, and 10c from leaking from a region between the transparent substrate 121 and the light emitting devices 10a, 10b, and 10c toward a side surface thereof, and may improve contrast of the display apparatus.

The light blocking layer 123 may have windows 123a, 123b, and 123c for a light path, so that light generated in the light emitting devices 10a, 10b, and 10c is incident on the transparent substrate 121, and for this purpose, the light blocking layer 123 on the transparent substrate 121 may be patterned to expose the transparent substrate 121. Widths of the windows 123a, 123b, and 123c may be narrower than those of the light emitting devices, but the inventive concepts are not limited thereto. For example, the widths of the windows 123a, 123b, and 123c may be larger than those of the light emitting devices 10a, 10b, and 10c, and accordingly, a gap between the light emitting devices 10a and the light blocking layer 123 may be formed.

The adhesive layer 125 is attached onto the transparent substrate 121. The adhesive layer 125 may cover the light blocking layer 123. The adhesive layer 125 may be attached onto an entire surface of the transparent substrate 121, but the inventive concepts are not limited thereto, and, in some exemplary embodiments, the adhesive layer 125 may be attached to a portion of the transparent substrate 121 to expose a region near an edge of the transparent substrate 121. The adhesive layer 125 is used to attach the light emitting devices 10a, 10b, and 10c to the transparent substrate 121. The adhesive layer 125 may fill the windows 123a, 123b, and 123c formed in the light blocking layer 123.

The adhesive layer 125 may be formed as a light-transmitting layer, and transmits light emitted from the light emitting devices 10a, 10b, and 10c. The adhesive layer 125 may be formed using an organic adhesive. For example, the adhesive layer 125 may be formed using a transparent epoxy. In addition, the adhesive layer 125 may include a diffuser such as SiO₂, TiO₂, ZnO, or the like to diffuse light. The light diffusing material prevents the light emitting devices 10a, 10b and 10c from being observed from the light exiting surface.

The first, second, and third light emitting devices 10a, 10b, and 10c are disposed on the transparent substrate 121. The first, second, and third light emitting devices 10a, 10b, and 10c may be attached to the transparent substrate 121 by the adhesive layer 125. The first, second, and third light emitting devices 10a, 10b, and 10c may be disposed to correspond to the windows 123a, 123b, and 123c of the light blocking layer 123.

The first, second, and third light emitting devices 10a, 10b, and 10c may be disposed on a flat surface of the adhesive layer 125 as illustrated in FIGS. 4B and 4C. The adhesive layer 125 may be disposed under lower surfaces of the light emitting devices 10a, 10b, and 10c. In some forms, the adhesive layer 125 may partially cover side surfaces of the first, second, and third light emitting devices 10a, 10b, and 10c.

The first, second, and third light emitting devices 10a, 10b, and 10c may be, for example, a red light emitting device, a green light emitting device, and a blue light emitting device. Since specific configurations of each of the first, second, and third light emitting devices 10a, 10b, and 10c are the same as those described with reference to FIG. 3A and FIG. 3B, detailed descriptions thereof will be omitted.

The first, second, and third light emitting devices 10a, 10b, and 10c may be arranged in a line, as illustrated in FIG. 4A. In particular, in a case that the transparent substrate 121 is a sapphire substrate, the sapphire substrate may include clean-cut surfaces (e.g., m-plane) and non-clean-cut surfaces (e.g., a-plane) due to a location of a crystal plane along a cutting direction. For example, when the sapphire substrate is cut into a quadrangular shape, two cutting planes on both sides thereof (e.g., m-plane) may be cut cleanly along the crystal plane, and two remaining cutting planes (e.g., a-plane) disposed in a direction perpendicular to the cutting planes may not be cut cleanly. In this case, the clean-cut surfaces of the sapphire substrate 121 may be flush with an arrangement direction of the light emitting devices 10a, 10b, and 10c. For example, in FIG. 4A, the clean-cut surfaces (e.g., m-plane) may be disposed up and down, and the two remaining cut surfaces (e.g., a-plane) may be disposed left and right.

In addition, each of the first, second, and third light emitting devices 10a, 10b, and 10c may be arranged parallel to one another in a long axis direction. Short axis directions of the first, second, and third light emitting devices 10a, 10b, and 10c may coincide with arrangement directions of these light emitting devices.

The first, second, and third light emitting devices 10a, 10b, and 10c may be those described above with reference to FIG. 3A and FIG. 3B, but the inventive concepts are not limited thereto, and various light emitting devices having a lateral or flip chip structure may be used.

The step adjustment layer 127 covers the first, second, and third light emitting devices 10a, 10b, and 10c and the adhesive layer 125. The step adjustment layer 127 has openings 127a exposing the first and second electrode pads 61 and 63 of the light emitting devices 10a, 10b, and 10c. The step adjustment layer 127 assists to securely form the connection layers by uniformly adjusting elevations of surfaces on which the connection layers 129a, 129b, 129c, and 129d are formed. The step adjustment layer 127 may be formed of, for example, photosensitive polyimide.

The step adjustment layer 127 may be disposed in a region surrounded by an edge of the adhesive layer 125, but the inventive concepts are not limited thereto. For example, the step adjustment layer 127 may be formed to partially expose the edge of the adhesive layer 125.

A side surface of the step adjustment layer 127 may be inclined at an angle of 90 degrees or less with respect to an upper surface of the adhesive layer 125. For example, the side surface of the step adjustment layer 127 may have an inclination angle of about 60 degrees with respect to the upper surface of the adhesive layer 125.

The first, second, third, and fourth connection layers 129a, 129b, 129c, and 129d are formed on the step adjustment layer 127. The connection layers 129a, 129b, 129c, and 129d may be connected to the first and second electrode pads 61 and 63 of the first, second, and third light emitting devices 10a, 10b, and 10c through the openings 127a of the step adjustment layer 127.

In an exemplary embodiment, as illustrated in FIGS. 4A and 4B, the first connection layer 129a may be electrically connected to a second conductivity type semiconductor layer of the first light emitting device 10a, the second connection layer 129b may be electrically connected to a second conductivity of the second light emitting device 10b, the third connection layer 129c may be electrically connected to a second conductivity type semiconductor layer of the third light emitting device 10c, and the fourth connection layer 129d may be commonly electrically connected to first conductivity type semiconductor layers of the first, second, and third light emitting devices 10a, 10b, and 10c. The first, second, third, and fourth connection layers 129a, 129b, 129c, and 129d may be formed together on the step adjustment layer 127, and may include, for example, Au.

In another exemplary embodiment, the first connection layer 129a may be electrically connected to the first conductivity type semiconductor layer of the first light emitting device 10a, the second connection layer 129b may be electrically connected to the first conductivity type semiconductor layer of the second light emitting device 10b, the third connection layer 129c may be electrically connected to the first conductivity type semiconductor layer of the third light emitting device 10c, and the fourth connection layer 129d may be commonly electrically connected to the second conductivity type semiconductor layers of the first, second, and third light emitting devices 10a, 10b, and 10c. The first, second, third, and fourth connection layers 129a, 129b, 129c, and 129d may be formed together on the step adjustment layer 127.

The insulation material layer 131 may be formed to have a thickness smaller than that of the step adjustment layer 127. A sum of the thicknesses of the insulation material layer 131 and the step adjustment layer 127 may be about 1 μm or more and 50 μm or less, but the inventive concepts are not limited thereto. Meanwhile, a side surface of the insulation material layer 131 may have an inclination angle of 90 degrees or less, for example, about 60 degrees with respect to the upper surface of the adhesive layer 125.

The insulation material layer 131 covers side surfaces of the step adjustment layer 127 and the connection layers 129a, 129b, 129c, and 129d. In addition, the insulation material layer 131 may cover a portion of the adhesive layer 125. The insulation material layer 131 may have openings 131a, 131b, 131c, and 131d exposing the connection layers 129a, 129b, 129c, and 129d, and accordingly, pad regions of the unit pixel 100 may be defined.

In an exemplary embodiment, the insulation material layer 131 may be a translucent material, and may be formed of an organic or inorganic material. The insulation material layer 131 may be formed of, for example, polyimide. When the insulation material layer 131 along with the step adjustment layer 127 is formed of polyimide, all of lower, side, and upper surfaces of the connection layers 129a, 129b, 129c, and 129d may be surrounded by the polyimide, except for the pad regions.

Meanwhile, the unit pixel 100 may be mounted on a circuit board using a bonding material such as solder, and the bonding material may bond the connection layers 129a, 129b, 129c, and 129d exposed to the openings 131a, 131b, 131c, and 131d of the insulation material layer 131 to pads on the circuit board.

According to the illustrated exemplary embodiment, the unit pixel 100 does not include separate bumps, and the connection layers 129a, 129b, 129c, and 129d are used as bonding pads. However, the inventive concepts are not limited thereto, and bonding pads covering the openings 131a, 131b, 131c, and 131d of the insulation material layer 131 may be formed. In an exemplary embodiment, the bonding pads may be formed to partially cover the light emitting devices 10a, 10b, and 10c outside of upper regions of the first, second, third, and fourth connection layers 129a, 129b, 129c, and 129d.

In the illustrated exemplary embodiment, the light emitting devices 10a, 10b, and 10c are described as being attached to the transparent substrate 121 by the adhesive layer 125, but the light emitting devices 10a, 10b, and 10c may be coupled to the transparent substrate 121 using another coupler instead of the adhesive layer 125. For example, the light emitting devices 10a, 10b, and 10c may be coupled to the transparent substrate 121 using spacers, and thus, gas or liquid may be filled in a region between the light emitting devices 10a, 10b, and 10c and the transparent substrate 121. An optical layer that transmits light emitted from the light emitting devices 10a, 10b, and 10c may be formed by the gas or liquid. The adhesive layer 125 described above is also an example of the optical layer. Herein, the optical layer is formed of a material such as gas, liquid, or solid, different from those of the light emitting devices 10a, 10b, and 10c, and thus, is distinguished from the materials of the semiconductor layers in the light emitting devices 10a, 10b, and 10c.

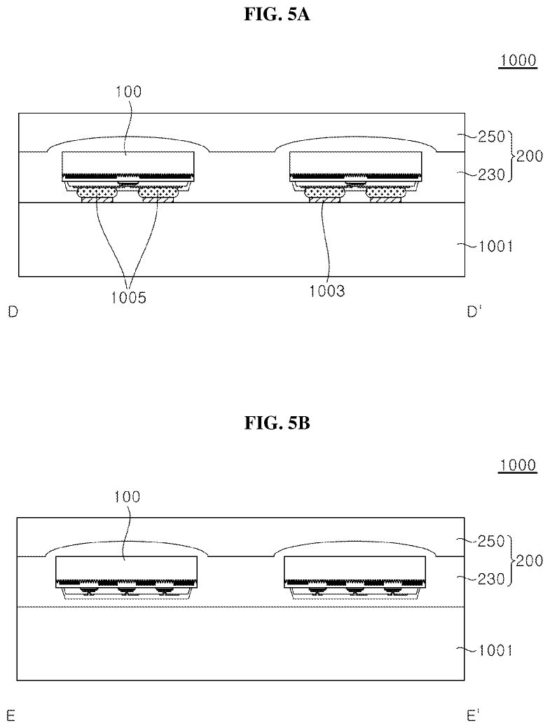

FIG. 5A is a schematic partial cross-sectional view taken along line D-D′ of FIG. 2 to illustrate the pixel module 1000 according to an exemplary embodiment, and FIG. 5B is a schematic partial cross-sectional view taken along line E-E′ of FIG. 2.

Referring to FIGS. 5A and 5B, the pixel module 1000 includes a circuit board 1001 and unit pixels 100 arranged on the circuit board 1001. The pixel module 1000 may further include a molding member 200 covering the unit pixels 100.

The circuit board 1001 may have a circuit for electrically connecting a panel substrate 2100 and light emitting devices 10a, 10b, and 10c. The circuit in the circuit board 1001 may be formed to have a multilayer structure. The circuit board 1001 may also include a passive circuit for driving the light emitting devices 10a, 10b, and 10c in a passive matrix driving manner or an active circuit for driving the light emitting devices 10a, 10b, and 10c in an active matrix driving manner. The circuit board 1001 may include pads 1003 exposed on a surface thereof.

Since a detailed configuration of the unit pixels 100 is the same as that described with reference to FIGS. 4A, 4B, and 4C, detailed descriptions thereof will be omitted to avoid redundancy. The unit pixels 100 may be arranged on the circuit board 1001. The unit pixels 100 may be arranged in various matrices such as 2×2, 2×3, 3×3, 4×4, 5×5, or the like.

The unit pixels 100 may be bonded to the circuit board 1001 by a bonding material 1005. For example, the bonding material 1005 bonds the connection layers 129a, 129b, 129c, and 129d exposed through the openings 131a, 131b, 131c, and 131d of the insulation material layer 131 to the pads 1003 on the circuit board 1001, as described with reference to FIGS. 4A, 4B, and 4C. The bonding material 1005 may be, for example, solder, and after a solder paste is disposed on the pads 1003 using a technique such as screen printing, may bond the unit pixel 100 and the circuit board 1001 through a reflow process. The pads 1003 on the circuit board 1001 may protrude above an upper surface of the circuit board 1001, but they may be disposed below the upper surface of the circuit board 1001.

According to the illustrated exemplary embodiment, the bonding material 1005 of a single structure is disposed between the connection layers 129a, 129b, 129c, and 129d and the pads 1003, and the bonding material 1005 may directly connect the connection layers 129a, 129b, 129c, and 129d and the pads 1003.

The molding member 200 covers a plurality of unit pixels 100. A total thickness of the molding member 200 may be in a range of about 150 μm to about 350 μm. The molding member 200 may include a light diffusion layer 230 and a black molding layer 250. The light diffusion layer 230 may include a transparent matrix such as an epoxy molding compound and light diffusion particles dispersed in the transparent matrix. The light diffusion particles may be, for example, silica or TiO₂, but the inventive concepts are not limited thereto. The molding member 200 may have a thickness in a range of, for example, about 50 μm to about 200 μm, and the light diffusion particles may be included in the molding member 200 within a range of, for example, about 0.2% to 10% by weight based on a total weight of the molding member 200. The light diffusion layer 230 diffuses light emitted from the light emitting devices 10a, 10b, and 10c. The light diffusion layer 230 assists to uniformly mix light of different colors emitted from the unit pixel 100 and also prevents light emitted to a side surface of the unit pixel 100 from emitting to the outside.

The black molding layer 250 includes a material that absorbs light in the matrix. The matrix may be, for example, a dry-film type solder resist (DFSR), a photoimageable solder resist (PSR), or an epoxy molding compound (EMC), but the inventive concepts are not limited thereto. The light absorbing material may include a light absorbing dye such as carbon black. The light absorbing dye may be directly dispersed in the matrix, or may be coated on a surface of organic or inorganic particles and dispersed in the matrix. Various kinds of organic or inorganic particles may be used to coat the light absorbing material. For example, TiO₂ or silica particles coated with carbon black may be used. The black molding layer 250 may be formed to have a thickness in a range of about 50 μm to about 200 μm. Light transmittance of the black molding layer 250 may be adjusted by adjusting a concentration of the light absorbing material contained in the black molding layer 250. The light absorbing material may be in a range of about 0.05% to about 10% by weight based on a total weight of the matrix.

The black molding layer 250 may be formed as a single layer in which the light absorbing material is uniformly dispersed, but the inventive concepts are not limited thereto. The black molding layer 250 may be formed of a plurality of layers having different concentrations of light absorbing materials from one another. For example, the black molding layer 250 may include two layers having different concentrations of light absorbing materials from each other. In this case, a first layer close to the light diffusion layer 230 may contain more light absorbing material than a second layer. Since a light absorption rate of the first layer is set to be higher than that of the second layer, a total absorption amount of light emitted upward from the unit pixel 100 may be reduced, and thus, luminance of the pixel module 1000 may be increased.

In an exemplary embodiment, when the black molding layer 250 is formed into the plurality of layers, these layers may have distinct boundaries to one another. For example, after layers having different concentrations of the light absorbing material from one another are individually manufactured as a film, the black molding layer 250 may be manufactured by sandwiching the films. Alternatively, the black molding layer 250 may be formed by continuously printing layers having different concentrations of the light absorbing material from one another. In another exemplary embodiment, the black molding layer 250 may be formed such that the concentration of the light absorbing material gradually decreases in a thickness direction.

Light vertically incident from the unit pixels 100 passes through the black molding layer 250 easily since a light path passing through the black molding layer 250 is short, but light incident with an inclination angle is mostly absorbed by the black molding layer 250 since a light path passing through the black molding layer 250 is long. As such, the black molding layer 250 prevents optical interference between the unit pixels 100, and thus, contrast of the display apparatus may be improved, thereby further reducing color deviation.

The molding member 200 may be formed using technology, for example, lamination, spin coating, slit coating, printing, or the like. For example, the molding member 200 may be formed on the unit pixels 100 by vacuum lamination technology after the light diffusion layer 230 and the black molding layer 250 are constricted.

A display apparatus 10000 may be provided by mounting the pixel modules 1000 on the panel substrate 2100 of FIG. 1 as illustrated in FIG. 5A and FIG. 5B. The circuit board 1001 has bottom pads connected to the pads 1003. The bottom pads may be arranged in a one-to-one correspondence with the pads 1003, but the number of the bottom pads may be reduced through a common connection.

In the illustrated exemplary embodiment, the display apparatus 10000 is provided as the unit pixels 100 are formed into the pixel module 1000, and the pixel modules 1000 are mounted on the panel substrate 2100, and thus, a process yield of the display apparatus may be improved. However, the inventive concepts are not limited thereto, and the unit pixels 100 may be directly mounted on the panel substrate 2100.

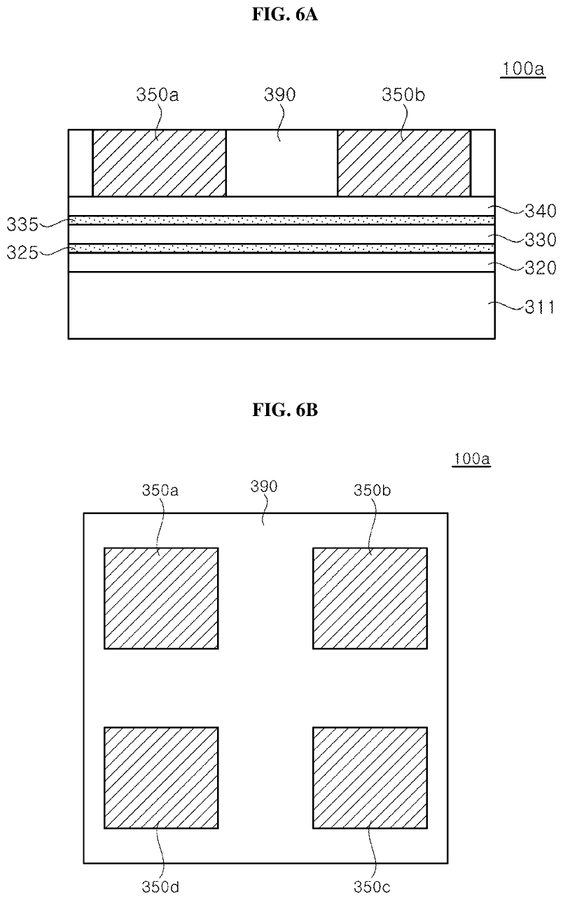

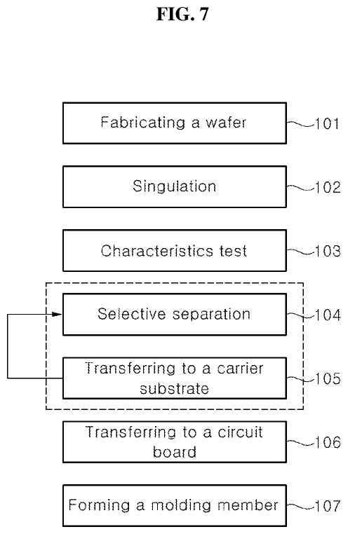

FIG. 6A is a schematic cross-sectional view illustrating a unit pixel 100a according to another exemplary embodiment, and FIG. 6B is a schematic plan view illustrating the unit pixel 100a.

Referring to FIGS. 6A and 6B, the unit pixel 100a, unlike the unit pixel 100 described with reference to FIGS. 4A, 4B, and 4C, has a structure in which first, second, and third light emitting stacks 320, 330, and 340 are stacked.

The unit pixel 100a includes a light emitting stack structure, a first connection electrode 350a, a second connection electrode 350b, a third connection electrode 350c, and a fourth connection electrode 350d formed on the light emitting stack structure, and a protection layer 390 surrounding the connection electrodes 350a, 350b, 350c, and 350d. The unit pixel 100a may also include a substrate 311. Meanwhile, the light emitting stack structure may include a first light emitting stack 320, a second light emitting stack 330, and a third light emitting stack 340. Although the light emitting stack structure is exemplarily illustrated as being composed of three light emitting stacks 320, 330, and 340, the present disclosure is not limited to a specific number of light emitting stacks. For example, in some exemplary embodiments, the light emitting stack structure may include two or more light emitting stacks. Herein, it will be described that the unit pixel 100a includes the three light emitting stacks 320, 330, and 340 according to an exemplary embodiment.

The substrate 311 may be a light-transmitting insulating substrate. However, in some exemplary embodiments, the substrate 311 may be formed to be translucent or partially transparent so as to transmit only light of a specific wavelength or only a portion of light of a specific wavelength. The substrate 311 may be a growth substrate capable of epitaxially growing the first light emitting stack 320, for example, a sapphire substrate. However, the substrate 311 is not limited to the sapphire substrate, and may include one of various other transparent insulating materials. For example, the substrate 311 may include glass, quartz, silicon, an organic polymer, or an organic-inorganic composite material, and the substrate 311 may be, for example, silicon carbide (SiC), gallium nitride (GaN), indium gallium nitride (InGaN), aluminum gallium nitride (AlGaN), aluminum nitride (AlN), gallium oxide (Ga₂O₃), or a silicon substrate. In addition, the substrate 311 may include irregularities on an upper surface thereof, and may be, for example, a patterned sapphire substrate. Since the irregularities on the upper surface is included, it is possible to increase extraction efficiency of light generated from the first light emitting stack 320 in contact with the substrate 311. The irregularities of the substrate 311 may be included so as to selectively increase luminous intensity of the first light emitting stack 320 compared to those of the second light emitting stack 330 and the third light emitting stack 340.

The first, second, and third light emitting stacks 320, 330, and 340 are configured to emit light toward the substrate 311. Accordingly, light emitted from the third light emitting stack 340 may pass through the first and second light emitting stacks 320 and 330. According to an exemplary embodiment, the first, second, and third light emitting stacks 320, 330, and 340 may emit light having different peak wavelengths from one another. In general, a light emitting stack far from the substrate 311 emits light of a longer wavelength than that of a light emitting stack close to the substrate 311, and thus, potential light loss may be reduced. However, in the present disclosure, to adjust a color mixing ratio of the first, second, and third light emitting stacks 320, 330, and 340, the second light emitting stack 330 may emit light of a shorter wavelength than that of the first light emitting stack 320. Accordingly, it is possible to reduce luminous intensity of the second light emitting stack 330 and increase luminous intensity of the first light emitting stack 320, and thus, a luminous intensity ratio of light emitted from the first, second, and third light emitting stacks may be dramatically modified. For example, the first light emitting stack 320 may be configured to emit green light, the second light emitting stack 330 may be configured to emit blue light, and the third light emitting stack 340 may be configured to emit red light. Accordingly, luminous intensity of blue light may be relatively reduced and luminous intensity of green light may be relatively increased, and thus, the luminous intensity ratio of red, green, and blue light may be easily adjusted to be close to 3:6:1. Moreover, a light emitting area of the first, second, and third light emitting stacks 320, 330, and 340 may be about 10,000 μm² or less, and further, 4,000 μm² or less. Additionally, the light emitting area may be 2,500 μm² or less. In addition, as the light emitting stack is closer to the substrate 311, the emitting area may become larger, and as the third light emitting stack 320 that emits green light is disposed closest to the substrate 311, luminance intensity of green light may be further increased.

As described with reference to FIGS. 3A and 3B, each of the first, second, and third light emitting stacks 320, 330, and 340 includes a first conductivity type semiconductor layer 21, an active layer 23, and a second conductivity type semiconductor layer 25. According to an exemplary embodiment, the first light emitting stack 320 may include a semiconductor material emitting green light such as GaN, InGaN, GaP, AlGaInP, AlGaP, or the like. The second light emitting stack 330 may include a semiconductor material emitting blue light such as GaN, InGaN, ZnSe, or the like, but the inventive concepts are not limited thereto. According to an exemplary embodiment, the third light emitting stack 340 may include, for example, a semiconductor material emitting red light such as AlGaAs, GaAsP, AlGaInP, and GaP, or the like, but the inventive concepts are not limited thereto.

According to an exemplary embodiment, each of the first conductivity type semiconductor layers 21 and the second conductivity type semiconductor layers 25 of the first, second, and third light emitting stacks 320, 330, and 340 may have a single layer structure or a multilayer structure, and in some exemplary embodiments, may include a super lattice layer. Moreover, the active layers 23 of the first, second, and third light emitting stacks 320, 330, and 340 may have a single quantum well structure or a multiple quantum well structure.

A first adhesive layer 325 is disposed between the first light emitting stack 320 and the second light emitting stack 330, and a second adhesive layer 335 is disposed between the second light emitting stack 330 and the third light emitting stack 340. The first and second adhesive layers 325 and 335 may include a non-conductive material that transmits light. For example, the first and second adhesive layers 325 and 335 may include an optically transparent adhesive (OCA), which may include epoxy, polyimide, SU8, spin-on-glass (SOG), benzocyclobutene. (BCB), but the inventive concepts are not limited thereto.

According to an exemplary embodiment, each of the first, second, and third light emitting stacks 320, 330, and 340 may be independently driven. More specifically, a common voltage may be applied to one of the first and second conductivity type semiconductor layers of each of the light emitting stacks, and an individual light emitting signal may be applied to the remaining one of the first and second conductivity type semiconductor layers of each of the light emitting stacks. According to an exemplary embodiment, the first conductivity type semiconductor layer 21 of each of the light emitting stacks may be n-type, and the second conductivity type semiconductor layer 25 may be p-type. In the first light emitting stack 320, the second light emitting stack 330, and the third light emitting stack 340, the n-type semiconductor layer and the p-type semiconductor layer may be arranged in an identical sequence, but the inventive concepts are not limited thereto. For example, the first light emitting stack 320 may have a reversely stacked sequence compared to those of the second light emitting stack 330 and the third light emitting stack 340. The first, second, and third light emitting stacks 320, 330, and 340 may have a common p-type light emitting stack structure in which the p-type semiconductor layers are commonly electrically connected, or may have a common n-type light emitting stack structure in which the n-type semiconductor layers are commonly electrically connected.

According to the illustrated embodiment, each of the connection electrodes 350a, 350b, 350c, and 350d may have a substantially elongated shape that protrudes upward from the substrate 311. The connection electrodes 350a, 350b, 350c, and 350d may include a metal such as Cu, Ni, Ti, Sb, Zn, Mo, Co, Sn, Ag, or alloys thereof, but the inventive concepts are not limited thereto. For example, each of the connection electrodes 350a, 350b, 350c, and 350d may include two or more metals or a plurality of different metal layers to reduce stress from the elongated shape of the connection electrodes 350a, 350b, 350c, and 350d. In another exemplary embodiment, in a case that the connection electrodes 350a, 350b, 350c, and 350d contain Cu, an additional metal may be deposited or plated to inhibit oxidation of Cu. In some exemplary embodiments, in a case that the connection electrodes 350a, 350b, 350c, and 350d include Cu/Ni/Sn, Cu may prevent Sn from permeating into the light emitting stack structure. In some exemplary embodiments, the connection electrodes 350a, 350b, 350c, and 350d may include a seed layer for forming a metal layer in a plating process, which will be described later.

As shown in FIGS. 6A and 6B, each of the connection electrodes 350a, 350b, 350c, and 350d may have a substantially flat upper surface, thereby facilitating electrical connection between the light emitting stack structure and an external line or an electrode which will be described later. According to the illustrated exemplary embodiment, the unit pixel 100a is micro LEDs having a surface area of about 10,000 μm² or less. In some forms, the surface area may be about 4,000 μm² or less, or more specifically, about 2,500 μm² or less. The connection electrodes 350a, 350b, 350c, and 350d may be overlapped with at least a portion of one of the first, second, and third light emitting stacks 320, 330, and 340 as shown in FIG. 6A. In the illustrated exemplary embodiment, the connection electrodes 350a, 350b, 350c, and 350d are illustrated as having a rectangular column shape, but the inventive concepts are not limited thereto, and may have a cylindrical shape. Furthermore, areas of lower surfaces of the connection electrodes 350a, 350b, 350c, and 350d may be larger than those of upper surfaces thereof. For example, when the first to third light emitting stacks 320, 330, and 340 are patterned for forming an electrode, the connection electrodes 350a, 350b, 350c, and 350d may cover side surfaces of the first to third light emitting stacks 320, 330, and 340.

In general, during a manufacturing process, an array of a plurality of unit pixels 100a is formed on the substrate 311. The substrate 311 is cut along a scribing line to singularize (separate) each of the unit pixels 100a, and the unit pixels 100a may be transported to another substrate or a tape using various transport techniques. In this case, when the unit pixel 100a includes the connection electrodes 350a, 350b, 350c, 350d such as metal bumps or pillars protruding outward, due to a structure exposing the connection electrodes 350a, 350b, 350c, 350d to the outside, during a subsequent process, for example, a transferring stage, various considerations may become relevant. In addition, in a case that the unit pixel 100a contains micro-LEDs with a surface area of about 10,000 μm² or less, of about 4,000 μm² or less, or about 2,500 μm² or less depending on an application, handling of the unit pixel 100a may present different consideration such as it becomes more difficult due to a small form factor.

For example, in the case that the connection electrodes 350a, 350b, 350c, and 350d have the substantially elongated shape such as a rod, transferring the unit pixel 100a using a conventional vacuum method may become difficult. This is because lack of a sufficient suction area due to the protruding structure of the connection electrodes. In addition, the exposed connection electrode may be directly affected by various stresses during a subsequent process, for example, when the connection electrode contacts a manufacturing apparatus, which may damage the structure of the unit pixel 100a. As another example, when the unit pixel 100a is transferred by attaching an adhesive tape on an upper surface of the unit pixel 100a (for example, a surface opposite to the substrate 311), a contact area between the unit pixel 100a and the adhesive tape may be limited to upper end surfaces of the connection electrodes 350a, 350b, 350c, and 350d. In this case, contrary to a case that the adhesive tape is attached to a lower surface of the substrate), adhesion of the unit pixel 100a to the adhesive tape may be weakened, and the unit pixel 100a may be undesirably separated from the adhesive tape while transferring the unit pixel 100a. As another example, when transferring the unit pixel 100a using a conventional pick-and-place method, an ejector pin may directly contact a portion of the unit pixel 100a, and thus, an upper structure of the light emitting structure may be damaged. In particular, the ejector pin may hit a center of the unit pixel 100a, and cause physical damage to an upper light emitting stack of the unit pixel 100a.

According to the illustrated exemplary embodiment, the protection layer 390 may be formed on the light emitting stack structure. More particularly, as shown in FIG. 6A, the protection layer 390 may be formed between the connection electrodes 350a, 350b, 350c, and 350d to cover side surfaces of the connection electrodes 350a, 350b, 350c, and 350d. Further, although the protection layer 390 is exemplarily illustrated as being disposed on the light emitting stack structure, the protection layer 390 may at least partially cover the side surfaces of the first to third light emitting stacks 320, 330, and 340, and the side surfaces of the first to third light emitting stacks 320, 330, and 340 may be covered with the protection layer 390 and another insulating layer so as not to be exposed to the outside of the unit pixel 100a.

The protection layer 390 may be formed to be substantially flush with the upper surfaces of the connection electrodes 350a, 350b, 350c, and 350d. The protection layer 390 may include an epoxy molding compound (EMC), which may be formed in various colors, such as black, white or transparent. However, the inventive concepts are not limited thereto. For example, in some exemplary embodiments, the protection layer 390 may include polyimide (PID), and in this case, PID may be provided as a dry film rather than a liquid type to increase flatness when PID is applied to the light emitting stack structure. In some exemplary embodiments, the protection layer 390 may include a photosensitive substance. In this manner, the protection layer 390 may provide a sufficient contact area to the unit pixel 100a not only to protect the light emitting structure from external impacts that may be applied during subsequent processes. The protection layer 390 also facilitates handling during a subsequent transferring step. In addition, the protection layer 390 may prevent light leakage from the side surface of the unit pixel 100a to prevent or at least to suppress interference of light emitted from an adjacent unit pixel 100a.

The unit pixels 100 and 100a, the pixel module 1000, and the display apparatus 10000 have been described above. The plurality of unit pixels 100 or 100a manufactured on a single wafer is divided into individual unit pixels through a singulation process, and the individual unit pixels 100 or 100a are transferred onto a circuit board or a display panel to manufacture the pixel module 1000 or the display apparatus 10000. The unit pixels 100 or 100a arranged in the pixel module 1000 or the display apparatus 10000 may be manufactured on a same wafer to one another or different wafers from one another. In general, the unit pixels 100 or 100a fabricated from different wafers from one another are disposed on a single display apparatus 10000. Performance of the unit pixels 100 or 100a needs to be strictly controlled so as to prevent occurrence of mura in an image displayed by the display apparatus 10000. In the pixel module 1000 or the display apparatus 10000 according to the illustrated exemplary embodiment, unlike those in the prior art, the unit pixels 100 or 100a having uniform performance are arranged, or even if there is a difference in performance, the unit pixels 100 or 100a having different performances are uniformly mixed and arranged to prevent locally brighter or darker occurrence of mura in the pixel module 1000 or the display device 10000.

Hereinafter, a process for disposing the unit pixels 100 manufactured from the wafer in the pixel module 1000 according to an exemplary embodiment will be described.

FIG. 7 is a schematic flowchart illustrating a manufacturing process of a display apparatus according to an exemplary embodiment.

Referring to FIG. 7, in Step 101, a wafer having a plurality of unit pixels 100 is fabricated. For example, a plurality of pixels including the unit pixel 100 described with reference to FIGS. 4A and 4B is formed on a single substrate 121. The substrate 121 may have a size of 4 inches, 6 inches, or larger than thereof, and the plurality of pixels may be formed by disposing light emitting devices 10a, 10b, and 10c on the substrate 121.

In Step 102, the plurality of pixels is singularized into individual unit pixels 100. The substrate 121 may be attached to, for example, a temporary substrate for singularizing the wafer, such as an adhesive tape, and the substrate 121 may be divided into the individual unit pixels 100 on the temporary substrate. The wafer may be divided into individual unit pixels 100 using a laser scribing and braking process. In addition, the unit pixels 100 attached onto the adhesive tape may be spaced apart from one another through expansion of the adhesive tape.

The temporary substrate may be, for example, an ultraviolet (UV) tape. The ultraviolet tape may be cured by UV irradiation, and adhesion may be reduced to about 1/100 or less, and further to about 1/200 or less by curing. For example, adhesion of the adhesive tape may be about 100 gf/mm before curing, and about 0.5 gf/mm after curing.

In the illustrated exemplary embodiment, the unit pixels 100 are described as being singularized on the ultraviolet tape. In other forms, the unit pixels 100 may be singularized on another adhesive tape and thereafter, transferred to the ultraviolet tape.

In Step 103, a characteristics test is carried out on the singularized unit pixels 100. The characteristics test of the unit pixels 100 may be carried out using a test device. For example, electrical characteristics and optical characteristics of each of the unit pixels 100 may be tested. A photoluminescence (PL) or electroluminescence (EL) method may be used to test characteristics of the respective unit pixels 100. Through this, data such as a forward voltage, luminance, an emission wavelength, and a viewing angle of each of the unit pixels 100 may be obtained. In addition, the unit pixels 100 may be classified through the test of characteristics. For example, the unit pixels 100 may be classified into No-good (NG) unit pixels that do not meet required performance, low-rank unit pixels that satisfy the required performance but have relatively low luminance, and high-rank unit pixels that satisfy the required performance and have a relatively high luminance. Criteria for classifying the unit pixels 100 may be various, and may be classified into two or more classes based on luminance.

In Step 104, the unit pixels 100 are selectively separated from the temporary substrate. According to an exemplary embodiment, unit pixels 100 within a predetermined area may be separated together from the temporary substrate, and unit pixels 100 selected from the plurality of unit pixels 100 within the predetermined area may be separated. The predetermined area may be determined corresponding to a size of a picker that transports the unit pixels. For example, 10 or more, 20 or more, or 30 or more unit pixels 100 may be disposed within the predetermined area. Meanwhile, among the unit pixels 100 on the temporary substrate, a method of selecting the unit pixels to be separated from the temporary substrate may be variously set.

In an exemplary embodiment, the unit pixels to be separated from the temporary substrate may be selected based on data from the characteristics test of the unit pixels. All unit pixels within the predetermined area may be selected, some unit pixels may be selected, or one unit pixel may be selected. For example, among the unit pixels within the predetermined area, defective unit pixels may be excluded from selection. Also, when all unit pixels within the predetermined area have an identical luminance, the all unit pixels may be selected together. In addition, unit pixels of an identical rank may be selected together excluding unit pixels of different ranks. Moreover, unit pixels having different ranks may be selected together using a preset program. For example, low-rank unit pixels and high-rank unit pixels may be selected together at a predetermined ratio. The exemplary embodiments of the present disclosure include selecting particular unit pixels from all unit pixels within the predetermined area or particular unit pixels and separating them from the temporary substrate.

In Step 105, the selectively separated unit pixel(s) are transferred to a carrier substrate. The carrier substrate may include an adhesive tape such as a blue tape. Among the unit pixels on the temporary substrate, the unit pixels to be transported to the carrier substrate are transported to the carrier substrate through several repeated selective separation (Step 104) and transferring (Step 105) processes. The unit pixels on an identical temporary substrate may be transported to a single carrier substrate, but the inventive concepts are not limited thereto. For example, the unit pixels on the identical temporary substrate may be divided into two or more carrier substrates and transported.

Meanwhile, the number of unit pixels arranged on the carrier substrate may be larger than that of the unit pixels fabricated on a single wafer. Accordingly, unit pixels fabricated from a plurality of wafers may be arranged on the single carrier substrate.

In Step 106, the unit pixels on the carrier substrate are transferred to the circuit board. The circuit board may be the panel substrate 2100 described with reference to FIG. 1 or the circuit board 1001 described with reference to FIG. 2. The unit pixels may be transferred onto the circuit board 1001 to manufacture the pixel module 1000, or may be directly transferred onto the panel substrate 2100 to manufacture the display apparatus 10000.

In Step 107, a molding member covering the transferred unit pixels on the circuit board is formed. Since the molding member is identical to that described with reference to FIGS. 5A and 5B, detailed descriptions thereof will be omitted. A plurality of pixel modules 1000 manufactured by forming the molding member may be mounted on the panel substrate 2100 to complete the display apparatus 10000. When the unit pixels are directly transferred onto the panel substrate 2100, the molding member may be formed on the panel substrate 2100, and accordingly, the display apparatus 10000 may be completed.

The unit pixels fabricated on the single wafer may differ in performance depending on their locations on the wafer. According to the illustrated exemplary embodiments, desired unit pixels among the unit pixels fabricated on the single wafer may be selectively separated and transferred to the carrier substrate, and the display apparatus may be manufactured using the unit pixels on the carrier substrate. As such, it is possible to prevent occurrence of mura in a displayed image.

The Steps 104 and 105 are repeatedly carried out several times, and a transferring apparatus for this will be used.

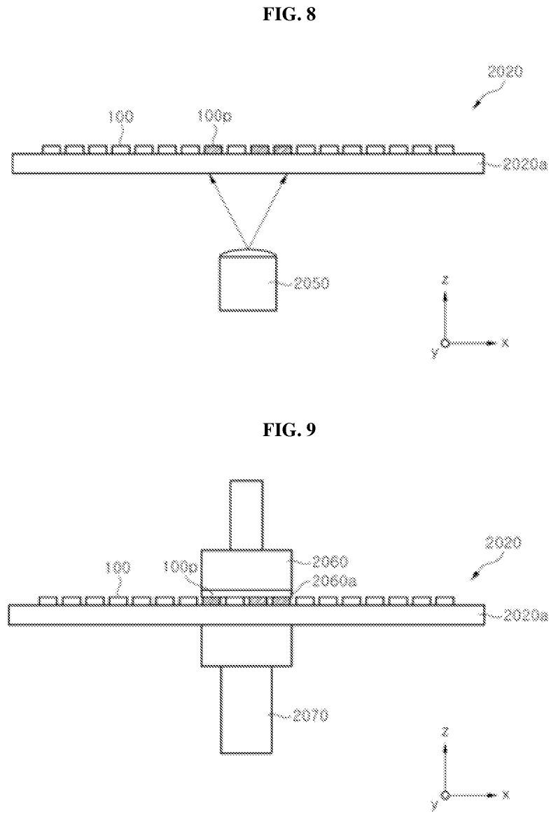

FIGS. 8 through 11 are schematic cross-sectional views illustrating a method of transferring unit pixels 100 to a carrier substrate 2090 using a transferring apparatus.

The unit pixels 100 are transferred from a temporary substrate 2020 to which singularized unit pixels 100 are attached to the carrier substrate 2090.

Referring to FIG. 8, ultraviolet rays are irradiated to unit pixels 100p to be separated from a base 2020a of the temporary substrate 2020 within a predetermined area. The base 2020a may be an ultraviolet tape. Ultraviolet rays may be sequentially irradiated to the unit pixels 100p using a light source unit 2050. The base 2020a is cured by UV irradiation, and adhesion of the unit pixels 100p is weakened.

Referring to FIG. 9, a picker unit 2060 moves onto the unit pixels 100p irradiated with ultraviolet rays, and a pickup head 2060a contacts the unit pixels. In addition, an ejector unit 2070 moves so that an ejector applies pressure to the temporary substrate 2020 against the pickup head 2060a. Accordingly, the unit pixels 100p within the predetermined area are attached to the pickup head 2060a.

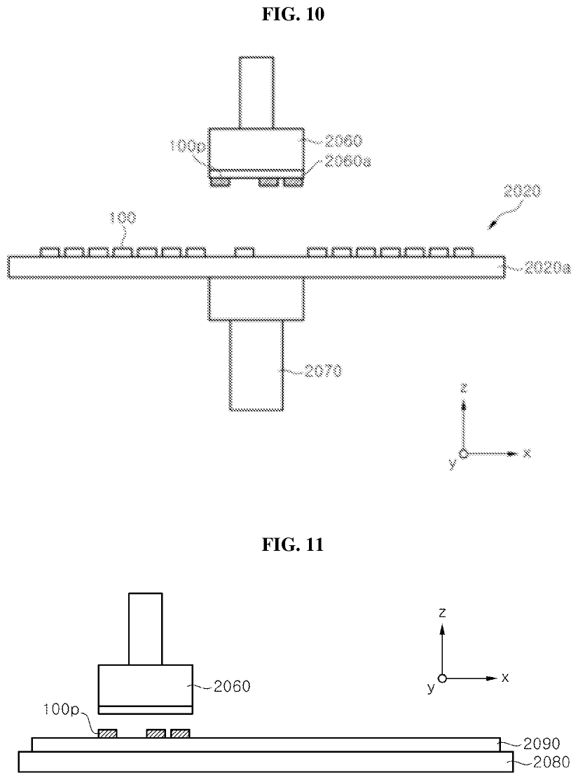

Referring to FIG. 10, when the pickup head 2060a moves in the z direction, the unit pixels 100p irradiated with ultraviolet rays are separated from the base 2020a. Since the unit pixels 100 that are not irradiated with ultraviolet rays are strongly adhered to the base 2020a, they are separated from the pickup head 2060a and remain on the base 2020a when the pickup head 2060a moves in the z direction.

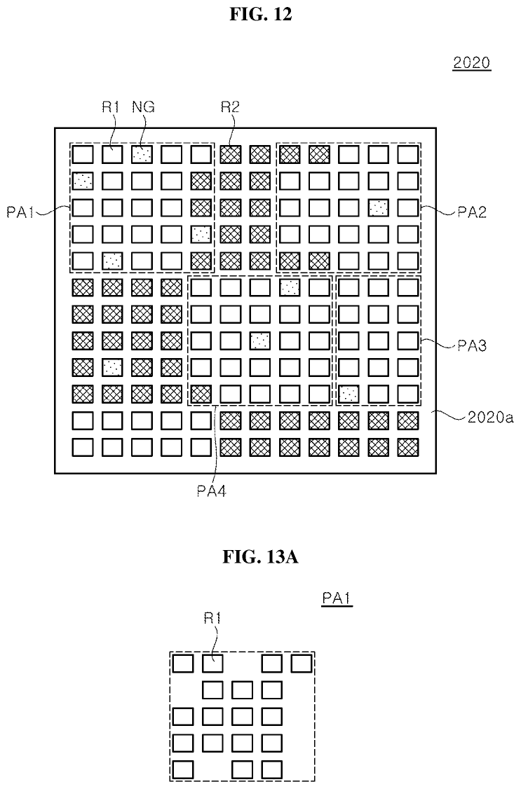

Referring to FIG. 11, the picker unit 2060 transfers the unit pixels 100 to the carrier substrate 2090. The carrier substrate 2090 may include, for example, a blue tape, and the blue tape has stronger adhesion to the unit pixels than the pickup head 2060a does. Accordingly, the unit pixels 100p moved by the picker unit 2060 may be transferred to the carrier substrate 2090 using the adhesion of the blue tape.

While the picker unit 2060 transfers the unit pixels 100p to the carrier substrate 2090, the light source unit 2050 may irradiate ultraviolet rays to the unit pixels 100p in another region. After the picker unit 2060 transfers the unit pixels 100p to the carrier substrate 2090, the picker unit 2060 moves to the temporary substrate 2020 again. By repeating the above-described operation, the picker unit 2060 transfers target unit pixels 100p on the temporary substrate 2020 to the carrier substrate 2090. When transferring of the unit pixels 100p on the temporary substrate 2020 is completed, transferring of unit pixels 100p on another temporary substrate 2020 may be performed.

Meanwhile, when the carrier substrate 2090 is filled with the unit pixels 100p, the unit pixels 100p on the carrier substrate 2090 may be pressed to have a uniform elevation from one another. While pressing the unit pixels 100p, heat may be applied.

Hereinafter, an exemplary embodiment of a method of selectively separating and transferring particular unit pixels 100p among the unit pixels on the temporary substrate 2020 to the carrier substrate 2090 will be described.

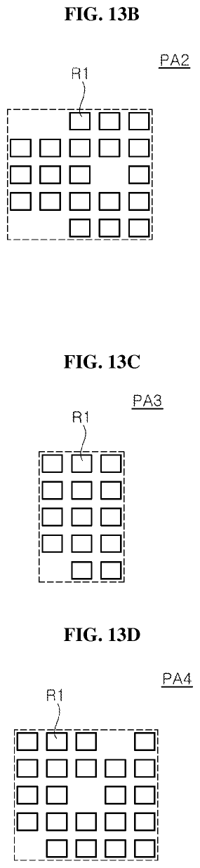

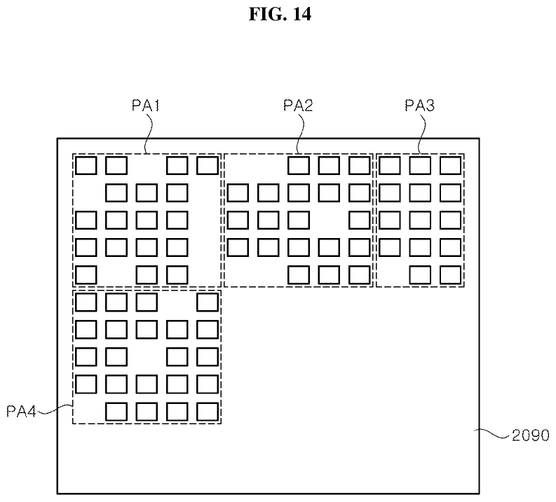

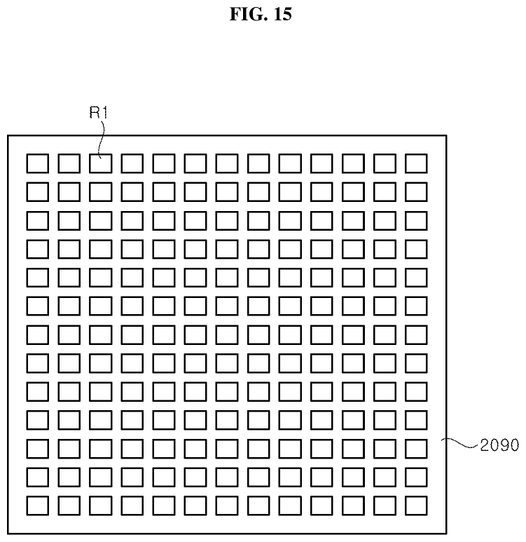

FIG. 12 is a schematic plan view of the temporary substrate 2020 to describe unit pixels before being transferred to the carrier substrate 2090 according to an exemplary embodiment, and FIGS. 13A through 13D are schematic plan views illustrating the unit pixels while being transferred to the carrier substrate 2090, FIG. 14 is a schematic plan view illustrating the carrier substrate 2090 during a process of transferring the unit pixels according to an exemplary embodiment, and FIG. 15 is a schematic plan view illustrating the carrier substrate 2090 on which transferring of the unit pixels is completed according to an exemplary embodiment.

First, referring to FIG. 12, the temporary substrate 2020 includes the base 2020a and unit pixels NG, R1, and R2 attached to the base. The base 2020a may be an ultraviolet tape being cured by ultraviolet irradiation.

The unit pixels may include no-good unit pixels NG with poor performance, high-rank unit pixels R1 with performance ranked above required specifications, and low-rank unit pixels R2 with performance ranked below the required specifications. In FIG. 13A, the high-rank unit pixels R1 are indicated by a square without hatching, the low-rank unit pixels R2 are indicated by an x-shaped hatching, and the no-good unit pixels NG are indicated by dot hatching. Performance to distinguish between the high and low-rank unit pixels R1 and R2 may be a forward voltage, luminance, or a viewing angle.

The unit pixels fabricated with a single wafer may include the no-good unit pixels NG, and in addition, the low-rank unit pixels R2 and the high-rank unit pixels R1 may be densely distributed at a specific location. Even when the no-good unit pixels NG are removed, in a case that a display apparatus is manufactured by transferring the low and high-rank unit pixels R1 and R2 while maintaining an identical positional relationship, in a region in which the high-rank unit pixels R1 are concentrated and in a region in which the low-rank unit pixels R2 are concentrated, luminance may be different from each other, for example, and thus, mura may occur in a displayed image. Accordingly, the high-rank unit pixels R1 and the low-rank unit pixels R2 are not transported to an identical carrier substrate 2090, but only unit pixels of an identical rank are transported to a single carrier substrate.

In FIG. 12, regions PA1, PA2, PA3, and PA4 indicated by dotted lines represent regions transported by the picker unit 2060. For example, the pickup head 2060a of the picker unit 2060 has an area corresponding to, for example, 5×5 unit pixels. That is, the pickup head 2060a may pick up a maximum of 25 unit pixels by way of example. By adjusting the area of the pickup head 2060a, 25 unit pixels or more or 25 unit pixels or fewer may be picked up at once.

First, the pickup head 2060a selectively picks up the high-rank unit pixels R1 in the first region PA1 and transports them to the carrier substrate 2090. The light source unit 2050 irradiates ultraviolet rays to the high-rank unit pixels R1 in the first region PA1, and thus, only the high-rank unit pixels R1 are separated from the temporary substrate 2020 by the pickup head 2060a. FIG. 13A shows the unit pixels R1 that are selectively separated from the first region PA1.

After transporting the high-rank unit pixels R1 in the first region PA1 to the carrier substrate 2090, the pickup head 2060a selectively picks up the high-rank unit pixels R1 in the second region PA2 and transports them to the carrier substrate 2090. FIG. 13B shows the unit pixels R1 that are selectively separated from the second region PA2. Like this, FIG. 13C shows the unit pixels R1 selectively separated from the third region PA3, and FIG. 13D shows the unit pixels R1 selectively separated from the fourth region PA4.

Meanwhile, FIG. 14 shows a state in which the unit pixels R1 selectively separated from the first to fourth regions PA1, PA2, PA3, and PA4 are transferred onto the carrier substrate 2090. The unit pixels R1 on the temporary substrate 2020 may be continuously transferred to the carrier substrate 2090 using the pickup head 2060a, and the unit pixels R1 are also transferred by the pickup head 2060a to portions of each of the regions PA1, PA2, PA3, and PA4 that do not have the unit pixels, so that the carrier substrate 2090 may be completely filled with the unit pixels R1 as shown in FIG. 15.

According to the illustrated exemplary embodiment, since only the high-rank unit pixels R1 are transferred to the carrier substrate 2090, when the display apparatus is manufactured using the unit pixels on the carrier substrate 2090, mura may be prevented from occurring in the image. In the illustrated exemplary embodiment, transferring of the high-rank unit pixels R1 to the carrier substrate 2090 is described, but the low-rank unit pixels R2 may be transferred to another carrier substrate 2090 in an identical manner. Accordingly, the display apparatus may be manufactured using only the low-rank unit pixels R2.

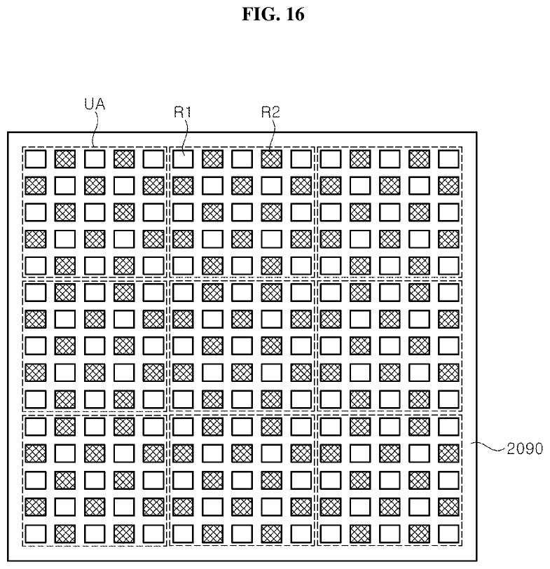

FIG. 16 is a schematic plan view illustrating a carrier substrate 2090 on which transferring of unit pixels is completed according to another exemplary embodiment.

Referring to FIG. 16, it has been described that the high-rank unit pixels R1 are transferred to the carrier substrate 2090 in the above-described embodiment, but the low-rank unit pixels R2 along with the high-rank unit pixels R1 are transferred to the carrier substrate 2090.

The high-rank unit pixels R1 and the low-rank unit pixels R2 are disposed together in a unit area UA corresponding to an area of the pickup head 2060a. The high-rank unit pixels R1 and the low-rank unit pixels R2 may be disposed at an identical ratio in each unit area UA, and further, locations of the high and low-rank unit pixels R1 and R2 disposed in each unit area UA may be identical. In the illustrated exemplary embodiment, the high-rank unit pixels R1 and the low-rank unit pixels R2 are arranged at a ratio of 13:12, but the inventive concepts are not limited thereto. However, the number of the high-rank unit pixels R1 and the low-rank unit pixels R2 may be identical for each unit area UA.

Although the high-rank unit pixels R1 and the low-rank unit pixels R2 are disposed together, but since each unit region includes the upper and low-rank unit pixels R1 and R2 of the identical ratio, it is possible to prevent occurrence of mura in a displayed image.

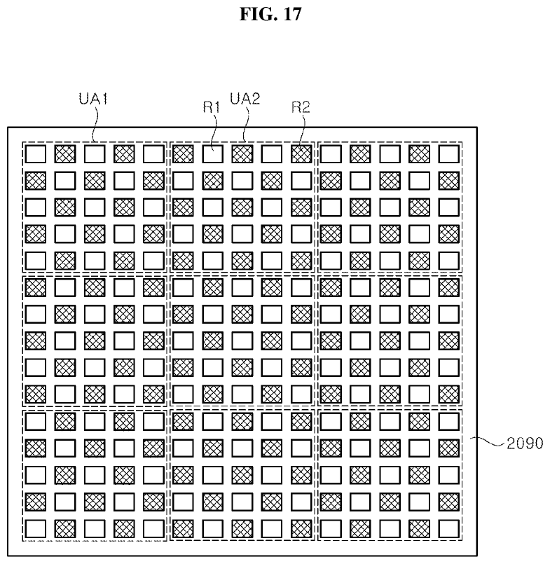

FIG. 17 is a schematic plan view illustrating a carrier substrate 2090 on which transferring of unit pixels R1 and R2 is completed according to another embodiment.

In the above exemplary embodiment (FIG. 16), it has been exemplarily described that the unit pixels R1 and R2 arranged in an identical manner are disposed adjacent to one another. Accordingly, the high-rank unit pixels R1 and the low-rank unit pixels R2 are alternately disposed within each unit area, but the high-rank unit pixels R1 or the low-rank unit pixels R2 may be disposed adjacent to one another between adjacent unit areas. However, in the illustrated exemplary embodiment, by adjusting arrangement of the high-rank unit pixels R1 and the low-rank unit pixels R2 in a first unit area UA1 and a second unit area UA2, even between adjacent unit areas UA1 and UA2, the high-rank unit pixels R1 or the low-rank unit pixels R2 may be disposed so as not to be adjacent to one another.

In the above exemplary embodiments, it has been exemplarily described that the high-rank unit pixels R1 and the low-rank unit pixels R2 are regularly arranged in a substantially similar number within the unit areas UA, UA1, and UA2, but the number of high-rank unit pixels R1 and low-rank unit pixels R2 do not need to be similar. The high-rank unit pixels R1 may be significantly more than the low-rank unit pixels R2, or vice versa. Further, the unit pixels R1 and R2 are not necessarily regularly arranged in the unit areas UA, UA1, and UA2. When a ratio of the high-rank unit pixels R1 and the low-rank unit pixels R2 is substantially constant, they may be arranged irregularly. Even when the high-rank unit pixels R1 and the low-rank unit pixels R2 are arranged irregularly, total luminance of the unit areas UA, UA1, and UA2 will be substantially uniform, and thus, it is possible to prevent occurrence of mura.

In the above embodiments, the method for transferring unit pixels and the transferring apparatus thereof have been described, but the transferring method and the transferring apparatus of the present disclosure are not limited to transferring unit pixels. For example, the transferring method and the transferring apparatus of the present disclosure may be used to transfer each sub-pixel, and thus, may be used to transfer individual light emitting devices, such as blue light emitting devices, green light emitting devices, or red light emitting devices.

Although some exemplary embodiments have been described herein, it should be understood that these exemplary embodiments are provided for illustration only and are not to be construed in any way as limiting the present disclosure. It should be understood that features or components of one exemplary embodiment can also be applied to other exemplary embodiments without departing from the spirit and scope of the present disclosure.

1. A light emitting device, comprising:
a substrate including a circuit;
a first light emitter electrically connected to the circuit and configured to emit a first light;
a second light emitter electrically connected to the circuit and configured to emit a second light having a longer peak wavelength than that of the first light; and
a third light emitter electrically connected to the circuit and configured to emit a third light having a longer peak wavelength than that of the second light,
wherein a luminous intensity of the third light is higher than a luminous intensity of the first light, and
wherein a luminous intensity of the second light is higher than the luminous intensity of the third light.

2. The light emitting device of claim 1, wherein the circuit includes pads and at least one of the pads is electrically connected to the first light emitter, the second light emitter, and the third light emitter.

3. The light emitting device of claim 2, wherein a number of the pads is larger than a number of light emitters.

4. The light emitting device of claim 2, further comprising a bonding layer disposed between at least one of the pads and at least one of the first light emitter, the second light emitter, or the third light emitter.

5. The light emitting device of claim 1, wherein the substrate includes a light transmitting material.

6. The light emitting device of claim 1, wherein the first light emitter includes a resin layer covering a region of the first light emitter.

7. The light emitting device of claim 6, wherein a side surface of the resin layer comprises a region inclined at an angle of 90 degrees or less with respect to upper surface of the resin layer.

8. The light emitting device of claim 6, wherein a side surface of the resin layer comprises a region inclined at an angle of 60 degrees or less with respect to upper surface of the resin layer.

9. The light emitting device of claim 1, wherein a luminous intensity ratio of the third light emitter, the second light emitter, and the first light emitter is adjusted to be close to 3:6: 1.

10. A light emitting device, comprising:
a substrate including a circuit;
a first light emitter disposed on the substrate and configured to emit a first light;
a second light emitter disposed on the substrate and configured to emit a second light having a different peak wavelength from that of the first light; and
a third light emitter electrically connected the circuit and configured to emit a third light having a different peak wavelength from that of the second light,
wherein a luminous intensity of the third light is higher than a luminous intensity of the first light, and
wherein a luminous intensity of the second light is higher than the luminous intensity of the third light.

11. The light emitting device of claim 10, wherein the second light has a longer peak wavelength than that of the first light.

12. The light emitting device of claim 10, wherein the third light has a longer peak wavelength than that of the second light.

13. The light emitting device of claim 10, wherein the second light emitter includes a resin layer covering a region of the second light emitter.

14. The light emitting device of claim 13, wherein a side surface of the resin layer comprises a region inclined at an angle of 90 degrees or less with respect to upper surface of the resin layer.

15. The light emitting device of claim 13, wherein a side surface of the resin layer comprises a region inclined at an angle of 60 degrees or less with respect to upper surface of the resin layer.

16. A light emitting device, comprising:
a substrate;
a first light emitter disposed on the substrate and configured to emit a first light;
a second light emitter disposed on the substrate and configured to emit a second light having a different peak wavelength from that of the first light; and
a third light emitter disposed on the substrate and configured to emit a third light having a different peak wavelength from that of the second light,
wherein a luminous intensity of the third light is higher than a luminous intensity of the first light, and
wherein a luminous intensity of the second light is higher than the luminous intensity of the third light.

17. The light emitting device of claim 16, wherein the substrate includes a circuit that includes pads and at least one of the pads is electrically connected to the first light emitter, the second light emitter, and the third light emitter.

18. The light emitting device of claim 17, wherein a number of the pads is larger than a number of light emitters.

19. The light emitting device of claim 16, wherein the first light emitter is configured to emit blue light, the second light emitter is configured to emit green light, and the third light emitter is configured to emit red light.

20. The light emitting device of claim 16, wherein a luminous intensity ratio of the third light emitter, the second light emitter, and the first light emitter is adjusted to be close to 3:6:1.
